(19) United States
(12) Patent Application Publication
(10) Pub. No.: US 2024/0297158 A1
(43) Pub. Date: Sep. 5, 2024

(54) MICRO LIGHT-EMITTING DIODE (LED) STRUCTURE

(71) Applicant: JADE BIRD DISPLAY (SHANGHAI) LIMITED, SHANGHAI (CN)

(72) Inventors: Yuankun ZHU, Shanghai (CN); Shuang ZHAO, Shanghai (CN); Deshuai LIU, Shanghai (CN)

(21) Appl. No.: 18/594,034

(22) Filed: Mar. 4, 2024

(30) Foreign Application Priority Data
Mar. 2, 2023 (WO) PCT/CN2023/079320

(51) Int. Cl. H01L 25/075; H01L 33/58; H01L 33/62

(52) U.S. Cl. CPC H01L 25/0753; H01L 33/58; H01L 33/62

(57) ABSTRACT

An exemplary micro light-emitting diode (LED) structure includes: a bottom epitaxial layer of a first conductive type; a light-emitting layer, formed on the bottom epitaxial layer; and a top epitaxial layer of a second conductive type, formed on the light-emitting layer. The top epitaxial layer comprises an array of first grooves dividing the micro LED structure into an array of micro LEDs.

### CROSS-REFERENCE TO RELATED APPLICATIONS

The present disclosure claims priority to and the benefits of PCT Application No. PCT/CN2023/079320, filed on Mar. 2, 2023, which is incorporated herein by reference in its entirety.

### TECHNICAL FIELD

The present disclosure generally relates to the technical field of micro light-emitting diodes (micro LEDs), and more particularly, to a micro LED structure that mitigates or prevents electrical current crosstalk between adjacent micro LEDs.

### BACKGROUND

The micro LED showed higher output performance than conventional LEDs due to better strain relaxation, improved light extraction efficiency, and uniform current spreading. The micro LEDs also exhibited improved thermal effects, higher current density, faster response rate, larger working temperature range, higher resolution, wider color gamut, higher contrast, and lower power consumption, as compared with conventional LEDs.

To achieve higher pixel density, the size of the micro LED is reduced to less than several micrometers. However, the efficiency and the carrier lifetime of the micro LED array-based device degrades drastically with reducing the micro LED size to a large extent, by surface recombination and poor p-type conduction induced by top-down etching. The performance of micro LED also suffers severely from quantum-confined stark effect, particularly due to the strain-induced polarization field, which leads to unstable operation, significant variations in emission wavelengths with increasing current. Additionally, with the decrease of the micro LED diameter, a large number of surface states and defects are formed at the surface of the micro LED structure by inductively coupled plasma (ICP) etching, which increases the non-radiation recombination at the surface of the micro LED structure.

Additionally, the emission of the conventional micro LED structure is mainly distributed at any direction which exhibits poor directional emission and reduces the light intensity along the vertical direction. To realize the directional emission of the micro LED structure, extra reflective structures are configured around the mesa of the micro LED structure and at the bottom of the mesa, so as to reflect the emission light to a same direction, which causes a complex manufacturing process and increases the cost of the micro LED.

To avoid the crosstalk between the adjacent micro LEDs, an isolation structure is conventionally formed outside and around a single micro LED, thereby increasing the volume of the micro LED and decreasing the integration of the micro display panel, and further reducing the resolution of the micro LED panel. Furthermore, the isolation structure is formed high enough to isolate the light crosstalk between the adjacent micro LEDs, thereby further increasing the volume of the micro LED. If the isolation structure is not formed at sufficient height, the crosstalk between the adjacent micro LEDs will not be efficiently inhibited.

Despite the above isolation structure, charge carriers may flow between adjacent micro LEDs, thereby causing electrical current crosstalk between neighboring pixels.

### SUMMARY

In view of the technical problem associated with the electrical current crosstalk in existing micro LED structures, the present disclosure provides micro LED structures that obviate this problem. Particularly, the disclosed micro LED structures (e.g., micro LED structure 100 in FIG. 1) include a continuous quantum well that is interconnected across the array of pixels. The disclosed micro LED structures also use a specially designed structure that causes the interconnected light-emitting layer to form charge-carrier depletion regions between adjacent pixels, so as to prevent electrical current crosstalk in the light-emitting layer.

According to some disclosed embodiments, an exemplary structure for a micro LED array is provided. The structure comprises: a bottom epitaxial layer of a first conductive type; a light-emitting layer, formed on the bottom epitaxial layer; and a top epitaxial layer of a second conductive type, formed on the light-emitting layer. The top epitaxial layer comprises an array of first grooves dividing the micro LED structure into an array of micro LEDs.

### BRIEF DESCRIPTION OF THE DRAWINGS

The accompanying drawings, which are incorporated in and constitute a part of this specification, illustrate embodiments consistent with the present disclosure and, together with the description, serve to explain the principles of the present disclosure.

FIG. 1 is a cross-sectional view schematically showing an exemplary micro LED structure, according to some embodiments of the present disclosure.

FIG. 2 is a schematic diagram illustrating a mechanism for mitigating electrical current crosstalk in a light-emitting layer of a micro LED structure, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

The present disclosure provides micro LED structures for use in a display device, e.g., micro LED display. As described above, a micro LED structure may include a light-emitting layer. In the present disclosure, the light-emitting layer is interconnected between adjacent pixels to form a continuous, integral light-emitting layer across the array of pixels of the micro LED structure. However, such an interconnected light-emitting layer may have charge carriers flowing across different pixels, thereby causing electrical current crosstalk between neighboring pixels. Therefore, the present disclosure further provides micro LED structures that obviate this problem,

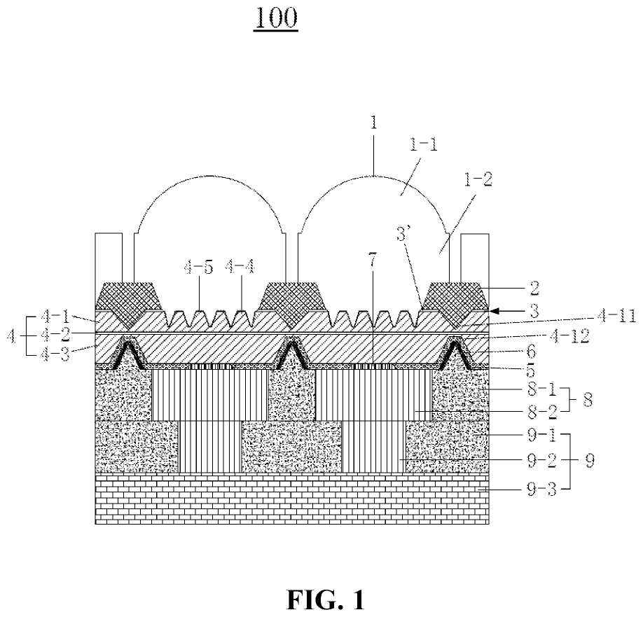

FIG. 1 is a cross-sectional view schematically showing an exemplary micro LED structure 100 that has improved light extraction efficiency, according to some embodiments of the present disclosure. More particularly, micro LED structure 100 includes an array of pixels implemented in an LED display device. FIG. 1 shows a portion of the array of pixels. As shown in FIG. 1, along a direction from a front side (i.e., a lens side) of micro LED structure 100 to a back side (i.e., a circuit side) of micro LED structure 100, it includes a micro lens layer 1, a top-connected structure 2, a top contact 3′, an epitaxial wafer 4, an insulating layer 5, a reflective layer 6, a bottom contact 7, a bottom conductive structure 8, and an integrated circuit (IC) backplane 9.

More specifically, as also shown in FIG. 1, in some embodiments, epitaxial wafer 4 includes a top epitaxial layer 4-1, a light-emitting layer 4-2, and a bottom epitaxial layer 4-3. Top epitaxial layer 4-1 is a semiconductor epitaxial layer with a first conductive type, and bottom epitaxial layer 4-3 is a semiconductor epitaxial layer with a second conductive type. As an example, the first conductive type is N-type, and the second conductive type is P-type. As another example, the first conductive type is P-type, and the second conductive type is N-type. The structures of these layers are described below in detail.

Top epitaxial layer 4-1 forms a top surface of epitaxial layer 4. Moreover, top epitaxial layer 4-1 forms a first array of grooves 4-11 on the top surface of epitaxial layer 4. Grooves 4-11 divide micro LED structure 100 into an array of pixels and are located at positions between adjacent pixels. Top epitaxial layer 4-1 may further include (not shown in FIG. 1): an n-GaAs (i.e., N-type GaAs) layer having a thickness between 10 nm-1000 nm, inclusive; and/or a Si-doped n-AlInP (i.e., N-type AlInP) layer having a thickness between 10 nm-10 micrometers, inclusive. The above exemplary numerical values are for illustrative purposes only, and are not intended to be used to limit the present disclosure.

In some embodiments, to improve the light extraction efficiency within micro LED structure 100, top epitaxial layer 4-1 is configured to form a plurality of photonic crystals 4-4 in each pixel. Photonic crystals 4-4 are formed at the top surface of top epitaxial layer 4-1 (i.e., the top surface of epitaxial wafer 4). In some embodiments, the top surface of photonic crystals 4-4 is covered by a passivation layer 4-5, to repair etching damages to photonic crystals 4-4. Herein, the bottom of the photonic crystals (4-4) is not lower than the bottom of the top epitaxial layer (4-1). Consistent with the disclosed embodiments, photonic crystals 4-4 may be configured to have shapes and sizes that are suitable for improving the light extraction efficiency. For example, as shown in FIG. 1, each of photonic crystals 4-4 may have a conical shape. As another example, each of the plurality of photonic crystals 4-4 has a height of approximately 300 nm and a diameter of approximately 266 nm, and adjacent photonic crystals 4-4 may be spaced by a distance of approximately 50 nm. Nonetheless, the disclosed embodiments are not limited to any particular shape or dimension of the photonic crystals. For example, each of the plurality of photonic crystals 4-4 may have a cylindrical shape (not shown in FIG. 1).

Bottom epitaxial layer 4-3 forms a bottom surface of epitaxial wafer 4. Bottom epitaxial layer 4-3 forms a second array of grooves 4-12 on the bottom surface of epitaxial wafer 4. Second array of grooves 4-12 are located at positions respectively corresponding to first array of grooves 4-11. Accordingly, like grooves 4-11, grooves 4-12 are also located between adjacent pixels. In some embodiments, bottom epitaxial layer 4-3 includes a Mg-doped p-AlInP layer having a thickness between 50 nm-300 nm, inclusive. These numerical values are for exemplary purposes only, and are not intended to be used to limit the present disclosure. As shown in FIG. 1, in some embodiments, bottom epitaxial layer 4-3 forms an array of inverted trapezoidal shapes or an array of bowl shapes.

Light-emitting layer 4-2 is between top epitaxial layer 4-1 and bottom epitaxial layer 4-3. Light-emitting layer 4-2 is interconnected and forms a continuous structure across the array of pixels. In some embodiments, light-emitting layer 4-2 includes one or more layers of an InGaP/AlGaInP quantum well, each layer of an InGaP/AlGaInP quantum well including an InGaP sub-layer and an AlGaInP sub-layer. For example, light-emitting layer 4-2 may include 1-20 layers of an InGaP/AlGaInP quantum well. As another example, in each layer of an InGaP/AlGaInP quantum well, the thickness of the InGaP sub-layer is approximately 3.5 nm, and the thickness of the AlGaInP sub-layer is approximately 6.5 nm. The above exemplary numerical values are for illustrative purposes only, and are not intended to be used to limit the present disclosure.

Micro lens layer 1 is disposed above top epitaxial layer 4-1, and includes an array of micro lenses 1 respectively corresponding to the array of pixels. Each of the micro lenses 1 includes a top hemisphere lens 1-1 and a lens base 1-2 below top hemisphere lens 1-1. A width of bottom spacer 1-2 is greater than a diameter of top hemisphere lens 1-1. A height of lens base 1-2 is dependent on the diameter of top hemisphere lens 1-1, e.g., the height of lens base 1-2 increases as the diameter of top hemisphere lens 1-1 increases. In some embodiments, top-connected structure 2 is a metal layer 2 which is disposed in the first array of grooves 4-11, and between the micro lens layer 1 and the top surface of epitaxial wafer 4. Gaps are formed between adjacent micro lenses 1, to expose metal layer 2 to air. Top contact layer 3 is disposed between metal layer 2 and the top surface of epitaxial wafer 4. In some embodiments, top contact layer 3 includes an array of top contacts 3′ respectively located in the array of pixels. The array of top contacts 3′ includes conductive material, such as pure metal or metal alloy. Each of top contact 3′ has a contact surface forming an ohmic contact with the top surface of epitaxial layer 4. In some embodiments, the contact surface is shaped as a quadrilateral with rounded corners. This shape results in a large contact area that facilities ohmic contact and electrical current expansion. An array of top contact (3′) disposed on the surface of the top epitaxial layer (4-1). Additionally the top-connected structure (2) is formed on the top contact (3′). Furthermore, the array of the top contact (3′) is respectively located in the array of micro LEDs. In the embodiment, the top contact (3′) is formed on a part of the top epitaxial layer (4-1) outside the sidewall of the first groove (4-11); and a part of the top-connected structure (2) is formed on the top contact (3′).

Bottom conductive structure 8 is disposed below bottom epitaxial layer 4-3. Insulating layer 5 is disposed in the second array of grooves 4-12. Reflective layer 6 is disposed in the second array of grooves 4-12, and between insulating layer 5 and bottom conductive structure 8. Bottom contact layer 7 is disposed between bottom conductive structure 8 and the bottom surface of epitaxial wafer 4. In some embodiments, bottom contact layer includes an array of bottom contact pads 7 respectively located in the array of pixels. The array of bottom contact pads 7 includes conductive material, such as pure metal or metal alloy. Each of bottom contact pads 7 is surrounded and insulated by insulating layer 5. Each of bottom contact pads 7 is electrically connected to bottom conductive structure 8.

Bottom conductive structure 8 is disposed on IC backplane 9. FIG. 1 shows an exemplary structure to achieve bonding between bottom conductive structure 8 and IC backplane 9. Specifically, bottom conductive structure 8 includes a first dielectric layer 8-1 and a first array of contact holes 8-2 formed in the first dielectric layer 8-1. Each contact hole 8-2 may have a cylindrical shape. A first metal is filled in the first array of cylindrical contact holes 8-2. IC backplane 9 includes a second dielectric layer 9-1, a second array of contact holes 9-2 formed in the second dielectric layer 9-1, and a chip circuit board 9-3 formed below the second dielectric layer 9-1 and the second array of contact holes 9-2. Each contact hole 9-2 may have a cylindrical shape. A second metal is filled in the second array of cylindrical contact holes 9-2. First array of contact holes 8-2 forms a one-to-one relationship with the second array of contact holes 9-2. Each contact hole 8-2 may have a width (or a diameter if contact hole 8-2 has a cylindrical shape) greater that the width (or diameter) of the corresponding contact hole 9-2. The first metal in the first array of cylindrical contact holes 8-2 is respectively bonded to second metal in the second array of cylindrical contact holes 9-2. In sum, the array of bottom contact pads 7 respectively corresponds to an array of pixels, and is electrically connected to the first metal in the first array of contact holes 8-2 respectively, which is further electrically connected to the second metal in the second array of contact holes 9-2 respectively.

Consistent with the disclosed embodiments, to improve the quantum wells' well plug effect (WPE) performance, light-emitting layer 4-2 is configured to form an integrated connected structure over the array of pixels, i.e., light-emitting layer 4-2 is interconnected across the array of pixels. “WPE” is defined as the ratio of optical output power over consumed electrical input power as measured at a wall plug. By forming light-emitting layer 4-2 as an integrated connected structure over the array of pixels, high WPE can be achieved in micro LED structure 100, thereby ensuring high performance of the LED display device.

However, interconnected light-emitting layer 4-2 may cause electrical current crosstalk in the array of pixels, particularly between adjacent pixels. The micro LED structures provided by the present disclosure obviate this problem. Specifically, as described above, top epitaxial layer 4-1 forms first array of grooves 4-11 on the top surface of epitaxial wafer 4. First array of grooves 4-11 divides the micro LED structure 100 into an array of pixels. That is, grooves 4-11 are located at positions between adjacent pixels. In some embodiments, each of grooves 4-11 has a bottom separated from light-emitting layer 4-2 by a distance between 50 nm-100 nm, inclusive. Moreover, bottom epitaxial layer 4-3 forms second array of grooves 4-12 on the bottom surface of epitaxial wafer 4 and at positions respectively corresponding to first array of grooves 4-11. That is, grooves 4-12 are also located at positions between adjacent pixels. In some embodiments, each of grooves 4-12 has a bottom (shown as the top of grooves 4-12 in FIG. 1) separated from light-emitting layer 4-2 by a distance between 50 nm-100 nm, inclusive. The above exemplary numerical values are for illustrative purposes only, and are not intended to be used to limit the present disclosure.

Moreover, as described above, the top-connected structure 2 is disposed in the first array of grooves 4-11. Because grooves 4-11 are located between adjacent pixels, the top-connected structure 2 is also located at the positions between adjacent pixels. As shown in FIG. 1, part of the top-connected structure 2 is also formed on and in contact with the top contact 3′. In the case that top contacts 3′ are respectively located in the array of micro LED, the top-connected structure 2 is formed on each of top contact 3′. In some embodiments, the array of first grooves 4-11 is interconnected across the array of micro LEDs. Accordingly, the top-connected structure 2 is also interconnected and forms an integral, continuous structure over the array of pixels. That is, the top-connected structure 2 is interconnected across the array of pixels.

Additionally, the first groove 4-11 is a sharp tip and the second groove 4-12 is a sharp tip. In some embodiments, the bottom of the first groove 4-11 is not lower than the bottom of the top epitaxial layer (4-1) and the bottom of the top epitaxial layer 4-1 is continuously formed in the micro LED array. Similarly, the top of the second groove 4-12 is not higher than the top of the bottom epitaxial layer 4-3, so the top of the bottom epitaxial layer 4-3 can be continuously formed in the micro LED array. As above mentioned, the array of the second grooves 4-12 is at positions respectively corresponding to the array of first grooves 4-11, and the top-connected structure 2 is disposed in the array of the first grooves 4-11 in the present embodiment. Furthermore, the second grooves 4-12 is formed at the edge of the position corresponding to a bottom contact; the bottom contact is formed at the bottom of the bottom epitaxial layer 4-3.

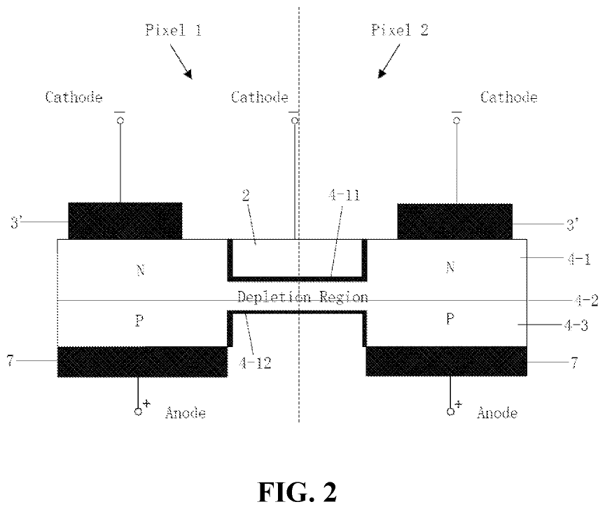

The above structure of array of first grooves 4-11, the top-connected structure 2, and/or array of second grooves 4-12 mitigates the electrical current crosstalk in light-emitting layer 4-2. FIG. 2 is a schematic diagram illustrating a mechanism mitigating electrical current crosstalk in light-emitting layer 4-2, according to some embodiments of the present disclosure. Specifically, FIG. 2 shows two adjacent pixels (Pixel 1 and Pixel 2) in micro LED structure 100 (FIG. 1), with light-emitting layer 4-2 being interconnected between the two adjacent pixels. As shown in FIG. 2, the first groove 4-11, the top-connected structure 2, and the second groove 4-12 are located at positions between the two adjacent pixels. Top contact 3′ in respective pixels forms a cathode, and bottom contact layer 7 in respective pixels forms an anode. Referring to FIG. 1, the top-connected structure 2 is in contact with the top contact 3′. Correspondingly, FIG. 2 shows the top-connected structure 2 is connected to top contact 3′. It is noted that, the top contact 3′ is continuously formed in the micro LED array and interconnected across the adjacent micro LEDs.

Still referring to FIG. 2, the top-connected structure 2, disposed in grooves 4-11, is close to light-emitting layer 4-2 and has a high work function. Accordingly, metal layer 2 (i.e., top-connected structure 2) and light-emitting layer 4-2 form a Schottky contact (i.e., contact between metal and semiconductor material). The Schottky contact causes electrons to flow from light-emitting layer 4-2 to metal layer 2, so as to generate an electric field in light-emitting layer 4-2 that depletes the charge carriers and creates a depletion region in light-emitting layer 4-2. The depletion region in light-emitting layer 4-2 is a high-resistance region between adjacent pixels, thereby preventing charge carriers flowing across different pixels. Therefore, the depletion region obviates electrical current crosstalk between different pixels.

Consistent with the disclosed embodiments, in contrast to the need to mitigate electrical current crosstalk in light-emitting layer 4-2, electrical current expansion between adjacent pixels is desirable in top epitaxial layer 4-1. Referring back to FIG. 1, in some embodiments, to enhance electrical current expansion performance between adjacent pixels, top epitaxial layer 4-1 is interconnected across the array of pixels, i.e., top epitaxial layer 4-1 forms an integral, continuous structure over the array of pixels. For example, top epitaxial layer 4-1 forms a continuous bottom surface across the array of pixels. In some embodiments, bottom epitaxial layer 4-3 is interconnected across the array of pixels. For example, bottom epitaxial layer 4-3 forms a continuous top surface across the array of pixels. Moreover, as described above, the top-connected structure 2 is disposed in the first array of grooves 4-11. In some embodiments, the array of first grooves 4-11 is interconnected across the array of micro LED, so the top-connected structure 2 is also interconnected across the array of pixels, i.e., the top-connected structure 2 forms an integral, continuous conductive structure over the array of pixels. Such top-connected structure 2 further enhances the current expansion performance between adjacent pixels.

Additionally or alternatively, as described above, each top contact 3′ has a contact surface in an ohmic contact with the top epitaxial layer 4-1. The contact surface may be shaped as a quadrilateral with rounded corners, which increases the contact area, thereby producing improved ohmic contact and electrical current expansion.

In summary, as described above, the disclosed micro LED structures (e.g., micro LED structure 100 in FIG. 1) include a continuous quantum well that is interconnected across the array of pixels. The disclosed micro LED structures also use a specially designed structure that causes the interconnected light-emitting layer to form charge-carrier depletion regions between adjacent pixels, so as to prevent electrical current crosstalk in the light-emitting layer.

In summary, the disclosed micro LED structures mitigate electrical current crosstalk in interconnected light-emitting layer 4-2. In particular, by forming the first array of grooves 4-11 on epitaxial wafer 4 and disposing interconnected metal layer 2 in the first array of grooves 4-11, charge-carrier depletion regions can be formed in light-emitting layer 4-2 and between adjacent pixels. As a result, electrical current crosstalk in interconnected light-emitting layer 4-2 can be prevented.

According to some disclosed embodiments, an exemplary micro LED structure includes: a micro lens layer; a metal layer; a top contact layer; an epitaxial wafer; an insulating layer; a reflective layer; a bottom contact layer; a bottom conductive structure; and an integrated circuit (IC) backplane. The epitaxial wafer includes: a top epitaxial layer forming a top surface of the epitaxial wafer, the micro lens layer being disposed above the top epitaxial layer; a bottom epitaxial layer forming a bottom surface of the epitaxial wafer, the bottom conductive structure being disposed below the bottom epitaxial layer; and a light-emitting layer between the top epitaxial layer and the bottom epitaxial layer. The top epitaxial layer includes a first array of grooves on the top surface, the first array of grooves dividing the micro LED structure into an array of pixels and having a bottom separated from the light-emitting layer by a distance between 50 nm-100 nm, inclusive. The top epitaxial layer includes a plurality of photonic crystals in each of the pixels and on the top surface, the plurality of photonic crystals being covered by a passivation layer. The bottom epitaxial layer includes a second array of grooves on the bottom surface and at positions respectively corresponding to the first array of grooves, the second array of grooves having a bottom separated from the light-emitting layer by a distance between 50 nm-100 nm, inclusive. The light-emitting layer is interconnected across the array of pixels. The metal layer is disposed in the first array of grooves, and between the micro lens layer and the top epitaxial layer. The top contact layer is disposed between the metal layer and the top epitaxial layer. The insulating layer is disposed in the second array of grooves. The reflective layer is disposed in the second array of grooves, and between the insulating layer and the bottom conductive structure. The bottom contact layer is disposed between the bottom epitaxial layer and the bottom conductive structure. The bottom conductive structure is disposed on the IC backplane.

By forming the first array of grooves and second array of grooves in the top epitaxial layer and bottom epitaxial layer, respectively, and with the bottoms of the first array of grooves and second array of grooves close to the light-emitting layer (e.g., within a distance between 50 nm-100 nm, inclusive), the disclosed micro LED structures allow the high-work-function metal layer to form a Schottky contact with the interconnected light-emitting layer, thereby generating an electric field in the light-emitting layer to deplete the charge carriers. Accordingly, regions with high electric resistance are created in the light-emitting layer and between adjacent pixels. These high-resistance regions prevent charge carriers flowing across adjacent pixels and thus mitigate electrical current crosstalk in the interconnected light-emitting layer.

According to some disclosed embodiments, the disclosed micro LED structures improve the light extraction efficiency of pixels by etching a structure of photonic crystals on the epitaxial wafer. Specifically, various shapes of photonic crystals can be used. And the photonic crystals in a micro LED structure can be arranged according to various pitches. For example, the shape of the photonic crystals can be cylindrical or conical. For another example, the pitch of the photonic crystals is determined by the etching depth and spacing distance between adjacent photonic crystals.

According to some disclosed embodiments, the photonic crystals are covered by a passivation layer, to repair etching damages to the photonic crystals.

According to some disclosed embodiments, the top contact layer includes an array of top contacts respectively located in the array of pixels. Each of the top contact has a contact surface forming an ohmic contact with the top epitaxial layer. The contact surface is shaped as a quadrilateral without round corners. This shape increases the contact area, and thus facilitates the ohmic contact and electrical current expansion in the top epitaxial layer.

According to some disclosed embodiments, the light-emitting layer is interconnected between adjacent pixels. Such interconnected quantum well structure enhances the performance of micro LED chips.

According to some disclosed embodiments, the top epitaxial layer is interconnected between adjacent pixels, so as to form an interconnected structure across the array of pixels. Such interconnected top epitaxial layer facilitates electrical current expansion.

According to some disclosed embodiments, the bottom epitaxial layer forms an array of inverted trapezoidal shapes or an array of bowl shapes at an interface between the bottom epitaxial layer and the bottom conductive structure. This way, the bottom of the inverted trapezoidal structure or bowl structures can reflect the light emitted from the quantum well to its periphery, so as to further gather the light and improve light utilization.

According to some disclosed embodiments, the bottom conductive structure includes a first dielectric layer and first metal. A first array of cylindrical contact holes is formed in the first dielectric layer and the first metal is filled in the first array of cylindrical contact holes. Moreover, the IC backplane includes a second dielectric layer, second metal, and a chip circuit board. The second dielectric layer includes a second array of cylindrical contact holes and the second metal is filled in the second array of cylindrical contact holes. The first metal in the first array of cylindrical contact holes is respectively bonded to the second metal in the second array of cylindrical contact holes. This way, the bottom conductive structure is bonded to the IC backplane.

According to some disclosed embodiments, the shape of the photonic crystals can be designed according to experimental data regarding the light extraction efficiency. For example, the photonic crystals may be designed to be cylindrical or conical. Such shapes generally can achieve satisfactory light extraction efficiency.

Consistent with the disclosed embodiments, the photonic crystals can have any suitable height, diameter, and/or spacing distance. For example, the photonic crystals may have a height of 300 nm, and/or a diameter of 266 nm. And adjacent photonic crystals may be separated by a spacing distance of 50 nm.

In summary of the present disclosure, the first array of grooves and second array of grooves are formed on the top epitaxial layer and bottom epitaxial layer, respectively, and separate the bottoms of the first array of grooves and second array of grooves from the light-emitting layer by a short distance (e.g., within a distance between 50 nm-100 nm, inclusive). This design allows the high-work-function metal layer to form a Schottky contact with the interconnected light-emitting layer, thereby generating an electric field in the light-emitting layer to deplete the charge carriers. Accordingly, regions with high electric resistance are created in the light-emitting layer and between adjacent pixels. These high-resistance regions prevent charge carriers flowing across adjacent pixels and thus mitigate electrical current crosstalk in the interconnected light-emitting layer.

Moreover, the photonic crystals formed on the top epitaxial layer are covered by a passivation layer to repair etching damages.

Moreover, the top contacts are shaped as quadrilaterals with round corners to increase the contact area between the top contacts and the top epitaxial layer. This design can improve ohmic contact between the top contacts and the top epitaxial layer, and improve electrical current expansion in the top epitaxial layer.

As used herein, unless specifically stated otherwise, the term “or” encompasses all possible combinations, except where infeasible. For example, if it is stated that a database may include A or B, then, unless specifically stated otherwise or infeasible, the database may include A or B, or A and B. As a second example, if it is stated that a database may include A, B, or C, then, unless specifically stated otherwise or infeasible, the database may include A, B, or C, or A and B, or A and C, or B and C, or A, B, and C.

It will be appreciated that the embodiments of the present disclosure are not limited to the exact construction that has been described above and illustrated in the accompanying drawings, and that various modifications and changes may be made without departing from the scope thereof. While the present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

What is claimed is:

1. A micro light-emitting diode (LED) structure, comprising:
a bottom epitaxial layer of a first conductive type;
a light-emitting layer, formed on the bottom epitaxial layer; and
a top epitaxial layer of a second conductive type, formed on the light-emitting layer;
wherein the top epitaxial layer comprises an array of first grooves dividing the micro LED structure into an array of micro LEDs.

2. The micro LED structure according to claim 1, wherein the array of first grooves is located at positions between adjacent micro LEDs and is interconnected across the array of micro LEDs.

3. The micro LED structure according to claim 1, wherein the array of first grooves has a bottom separated from the light-emitting layer by a distance between 50 nm-100 nm, inclusive.

4. The micro LED structure according to claim 1, wherein each first groove has a sharp tip.

5. The micro LED structure according to claim 1, wherein a bottom of the array of first grooves is higher than a bottom of the top epitaxial layer.

6. The micro LED structure according to claim 1, wherein the bottom epitaxial layer comprises an array of second grooves.

7. The micro LED structure according to claim 6, wherein a top of the array of second grooves is lower than a top of the bottom epitaxial layer.

8. The micro LED structure according to claim 6, further comprising:
a top-connected structure disposed in the array of the first grooves, wherein the array of the second grooves is at positions respectively corresponding to the array of first grooves.

9. The micro LED structure according to claim 6, further comprising:
an array of bottom contacts formed at a bottom surface of the bottom epitaxial layer, the array of bottom contacts respectively corresponding to the array of micro LED, wherein the array second grooves is formed at positions corresponding to an edge of the array of bottom contacts.

10. The micro LED structure according to claim 6, wherein each second groove has a sharp tip.

11. The micro LED structure according to claim 6, wherein the array of second grooves (4-12) has a bottom separated from the light-emitting layer by a distance between 50 nm-100 nm, inclusive.

12. The micro LED structure according to claim 1, further comprising:
a top-connected structure disposed in the array of first grooves; a bottom conductive structure formed below the bottom epitaxial layer, wherein the top-connected structure is interconnected across the array of micro LEDs.

13. The micro LED structure according to claim 1, further comprising a micro lens layer formed on the top epitaxial layer.

14. The micro LED structure according to claim 13, wherein the micro lens layer comprises an array of micro lenses respectively corresponding to the array of micro LEDs.

15. The micro LED structure according to claim 14, further comprising:
a top-connected structure disposed in the array of first grooves, wherein gaps are formed between adjacent micro lenses, the gaps exposing a metal layer to air.

16. The micro LED structure according to claim 14, wherein each of the micro lenses comprises a top hemisphere lens and a bottom spacer below the top hemisphere lens.

17. The micro LED structure according to claim 16, wherein a width of the bottom spacer is greater than a diameter of the top hemisphere lens.

18. The micro LED structure according to claim 16, wherein a height of the bottom spacer is dependent on a diameter of the top hemisphere lens.

19. The micro LED structure according to claim 1, further comprising:
an array of top contacts disposed on the top epitaxial layer; and
a top-connected structure formed on the array of top contacts, wherein the array of top contacts is respectively located in the array of micro LEDs.

20. The micro LED structure according to claim 19, wherein:
the array of top contacts is formed on a part of the top epitaxial layer outside the array of first grooves; and
the top-connected structure is partially formed on the array of top contacts.

21. The micro LED structure according to claim 19, wherein each of the top contacts has a contact surface forming an ohmic contact with the top epitaxial layer, the contact surface being shaped as a quadrilateral with rounded corners.

22. The micro LED structure according to claim 1, further comprising an insulating layer formed at a bottom surface of the bottom epitaxial layer.

23. The micro LED structure according to claim 22, wherein:
the bottom epitaxial layer comprises an array of second grooves; and
the insulating layer is disposed in the array of second grooves.

24. The micro LED structure according to claim 22, further comprising an array of bottom contacts formed in the insulating layer and at the bottom surface of the bottom epitaxial layer, the array of bottom contacts respectively corresponding to the array of micro LEDs.

25. The micro LED structure according to claim 24, further comprising:
a bottom conductive structure formed below the bottom epitaxial layer,
wherein each of the contacts is surrounded by the insulating layer and electrically connected to the bottom conductive structure.

26. The micro LED structure according to claim 22, further comprising:
an array of second grooves formed at a bottom surface of the bottom epitaxial layer;
a bottom conductive structure formed below the bottom epitaxial layer; and
a reflective layer formed between the insulating layer and the bottom conductive structure, wherein the reflective layer is disposed in the second array of grooves.

27. The micro LED structure according to claim 1, wherein the bottom epitaxial layer forms an array of inverted trapezoidal shapes or an array of bowl shapes.

28. The micro LED structure according to claim 1, further comprising:
a bottom conductive structure formed below the bottom epitaxial layer; and an integrated circuit (IC) backplane formed below and electrically connected to the bottom conductive structure.

29. The micro LED structure according to claim 28, wherein:
the bottom conductive structure comprises a first dielectric layer and a first array of contact holes formed in the first dielectric layer; and
the IC backplane comprises a second dielectric layer and a second array of contact holes formed in the second dielectric layer, the second array of contact holes respectively corresponding to the first array of contact holes.

30. The micro LED structure according to claim 29, wherein a first metal is filled in the first array of contact holes and a second metal is filled in the second array of contact holes, the first metal in the first array of contact holes being respectively bonded to the second metal in the second array of contact holes.

31. The micro LED structure according to claim 30, further comprising:
an array of contact pads formed at a bottom surface of the bottom epitaxial layer, the array of contact pads being electrically connected to the first metal in the array of contact holes, respectively.

32. The micro LED structure according to claim 29, wherein the IC backplane further comprises:
a chip circuit board formed below the second dielectric layer and the second array of contact holes.

33. The micro LED structure according to claim 1, wherein the top epitaxial layer comprises a plurality of photonic crystals in each of the micro LED.

34. The micro LED structure according to claim 33, wherein a bottom of the plurality of the photonic crystals is not lower than a bottom of the top epitaxial layer.

35. The micro LED structure according to claim 33, further comprising a passivation layer formed on the plurality of photonic crystals.

36. The micro LED structure according to claim 33, wherein each of the plurality of photonic crystals has a cylindrical shape or a conical shape.

37. The micro LED structure according to claim 33, wherein each of the plurality of photonic crystals has a height of 300 nm and a diameter of 266 nm, and adjacent photonic crystals are spaced by a distance of 50 nm.

38. The micro LED structure according to claim 1, wherein:
the first conductive type is N-type and the second conductive type is P-type; or the first conductive type is P-type and the second conductive type is N-type.

39. The micro LED structure according to claim 1, wherein the light-emitting layer is interconnected across the array of micro LEDs.

40. The micro LED structure according to claim 1, wherein the top epitaxial layer is interconnected across the array of micro LEDs.

41. The micro LED structure according to claim 40, wherein the top epitaxial layer forms a continuous bottom surface across the array of micro LEDs.

42. The micro LED structure according to claim 1, wherein the bottom epitaxial layer is interconnected across the array of micro LEDs.

43. The micro LED structure according to claim 42, wherein the bottom epitaxial layer forms a continuous top surface across the array of micro LEDs.
